(19) United States
(12) Patent Application Publication
(10) Pub. No.: US 2024/0334780 A1
(43) Pub. Date: Oct. 3, 2024

(54) DISPLAY PANEL AND FABRICATION METHOD THEREOF, AND ELECTRONIC DEVICE

(71) Applicant: Shenzhen China Star Optoelectronics Semiconductor Display Technology Co., Ltd., Shenzhen, Guangdong (CN)

(72) Inventor: Ming XU, Shenzhen, Guangdong (CN)

(21) Appl. No.: 17/595,949

(22) PCT Filed: Oct. 29, 2021
(86) PCT No.: PCT/CN2021/127414

§ 371 Date: Jun. 5, 2024

(30) Foreign Application Priority Data
Oct. 26, 2021 (CN) 202111250395.7

(51) Int. Cl. H10K 59/80; H10K 59/12; H10K 59/122

(52) U.S. Cl. CPC H10K 59/80516; H10K 59/1201; H10K 59/122

(57) ABSTRACT

The present application provides a display panel and a fabrication method thereof, and an electronic device. The display panel includes a substrate, a pixel defining layer, an auxiliary electrode, a conductive protrusion, and a first electrode. A first opening is defined in the pixel defining layer. The auxiliary electrode is arranged in the first opening. The conductive protrusion is arranged on a side of the auxiliary electrode away from the substrate and is connected to the auxiliary electrode. The first electrode is arranged on a side of the conductive protrusion away from the auxiliary electrode, and extends from an inner wall of the first opening to a surface of the conductive protrusion and is connected to the conductive protrusion.

### FIELD OF INVENTION

The present application relates to a display technology field, and particularly to a display panel and a fabrication method thereof, and an electronic device.

### BACKGROUND

Top-emitting organic light-emitting diode (OLED) display products have various application prospects, but this type of OLED display panel requires a higher transparency of a top electrode. Under normal circumstances, a thickness of the top electrode needs to be strictly controlled to meet requirements of the top-emitting OLED display panels. For example, if a metal (such as magnesium-silver alloy) is used as a material of the top electrode, the thickness of the top electrode needs to be controlled less than 20 nm to meet transparency requirements. However, within the above-mentioned thickness range, cross-sectional currents of the top electrode will be greatly limited, and thus exhibit poor conductivity. Especially, if such type of top electrode is applied to large-size OLED display panels, due to distances of the supplying circuits, different levels of IR drop in different areas of the display panels are caused, which result in poor display uniformity of the display panel.

### SUMMARY OF DISCLOSURE

### Technical Problem

In order to solve above technical problems, auxiliary electrodes are usually arranged in display areas when preparing an existing OLED display panel, and the top electrode is connected to the auxiliary electrode, and the IR drop is reduced by making the top electrode potentials in different areas consistent. However, after forming the auxiliary electrode, it is usually necessary to fabricate an organic layer over an entire surface before fabricating the top electrode. Since the auxiliary electrode is covered by the organic layer provided on the entire surface, it is difficult to form an effective connection between the last formed top electrode and the auxiliary electrode. Therefore, the IR drop of the display panel cannot be effectively reduced, and the display uniformity of the display panel is still difficult to be improved.

### Solutions to the Technical Problem

### Technical Solutions

The embodiments of the present application provide a display panel and a fabrication method thereof, and an electronic device to solve the technical problem that it is difficult to form an effective overlap between the top electrode and the auxiliary electrode in the OLED display panel, and to improve the display uniformity.

An embodiment of the present application provides a display panel, comprising a substrate;
a pixel defining layer arranged on a side of the substrate, wherein a first opening is defined in the pixel defining layer;
an auxiliary electrode arranged on a side of the substrate, wherein the auxiliary electrode is arranged in the first opening;
a conductive protrusion arranged on a side of the auxiliary electrode away from the substrate, wherein the conductive protrusion is connected to the auxiliary electrode; and
a first electrode arranged on a side of the conductive protrusion away from the auxiliary electrode, wherein the first electrode extends from an inner wall of the first opening to a surface of the conductive protrusion and is connected to the conductive protrusion.

Optionally, in some embodiments of the present application, the display panel further comprises a light-emitting functional layer, wherein the light-emitting functional layer is located between the auxiliary electrode and the first electrode, and a second opening is defined in the light-emitting functional layer, and the second opening exposes at least a part of the conductive protrusion, and the first electrode is connected to the exposed part of the conductive protrusion.

Optionally, in some embodiments of the present application, the light-emitting functional layer covers an edge of the conductive protrusion.

Optionally, in some embodiments of the present application, the light-emitting functional layer and the conductive protrusions are spaced apart, the second opening also exposes a part of the auxiliary electrode, and the first electrode is respectively connected to the conductive protrusion and the exposed part of the auxiliary electrode.

Optionally, in some embodiments of the present application, the display panel further comprises a limiting portion, and the limiting portion is arranged on the auxiliary electrode and located on a periphery of the conductive protrusion.

Optionally, in some embodiments of the present application, the conductive protrusion comprises at least two conductive protrusion portions, the at least two conductive protrusion portions are arranged adjacent to each other, the limiting portion is arranged on the periphery of each of the conductive protrusion portion, and the first electrode is respectively connected with the at least two conductive protrusion portions.

Optionally, in some embodiments of the present application, the limiting portion is arranged in the second opening, the second opening exposes at least a part of the limiting portion, the limiting portion is a conductive structure, and the first electrode is respectively connected with the conductive protrusion and the exposed part of the limiting portion.

Optionally, in some embodiments of the present application, the limiting portion and the auxiliary electrode are integrally formed.

Optionally, in some embodiments of the present application, a groove is defined in the auxiliary electrode, and the conductive protrusion is arranged in the groove.

Optionally, in some embodiments of the present application, a surface of the groove close to the conductive protrusion is a first contact surface, a surface of the conductive protrusion close to the groove is a second contact surface, and the first contact surface and the second contact surface are connected and matched.

Optionally, in some embodiments of the present application, an orthographic projection of the conductive protrusion on a plane where the substrate is located is within an orthographic projection of the auxiliary electrode on the plane where the substrate is located.

Optionally, in some embodiments of the present application, the display panel comprises an auxiliary electrode area and a light-emitting pixel area that are adjacently arranged, the first opening is defined in the auxiliary electrode area, a third opening is defined in the pixel defining layer, and the third opening is defined in the light-emitting pixel area;

and the display panel further comprises a second electrode arranged on the substrate and defined in the third opening, the second electrode and the auxiliary electrode are arranged in the same layer, and the second electrode is arranged in the light-emitting pixel area.

An embodiment of the present application provides an electronic device, wherein the electronic device comprises a housing and a display panel arranged in the housing, and the display panel comprises:
a substrate;
a pixel defining layer arranged on a side of the substrate, wherein a first opening is defined in the pixel defining layer;
an auxiliary electrode arranged on a side of the substrate, wherein the auxiliary electrode is arranged in the first opening;
a conductive protrusion arranged on a side of the auxiliary electrode away from the substrate, wherein the conductive protrusion is connected to the auxiliary electrode; and
a first electrode arranged on a side of the conductive protrusion away from the auxiliary electrode, wherein the first electrode extends from an inner wall of the first opening to a surface of the conductive protrusion and is connected to the conductive protrusion.

Optionally, in some embodiments of the present application, the display panel further comprises a light-emitting functional layer, wherein the light-emitting functional layer is located between the auxiliary electrode and the first electrode, and a second opening is defined in the light-emitting functional layer, and the second opening exposes at least a part of the conductive protrusion, and the first electrode is connected to the exposed part of the conductive protrusion.

Optionally, in some embodiments of the present application, the light-emitting functional layer and the conductive protrusion are spaced apart, the second opening also exposes a part of the auxiliary electrode, and the first electrode is respectively connected to the conductive protrusion and the exposed part of the auxiliary electrode.

Optionally, in some embodiments of the present application, the display panel further comprises a limiting portion, and the limiting portion is arranged on the auxiliary electrode and located on a periphery of the conductive protrusion.

An embodiment of the present application provides a fabrication method of a display panel, comprising following steps:
providing a substrate;
forming a pixel defining layer and an auxiliary electrode on a side of the substrate, wherein the pixel defining layer is defined with a first opening, and the auxiliary electrode is arranged in the first opening;
forming a conductive protrusion on a side of the auxiliary electrode away from the substrate, wherein the conductive protrusion is connected to the auxiliary electrode;
forming a light-emitting functional layer on a side of the conductive protrusion away from the auxiliary electrode, wherein the light-emitting functional layer covers the conductive protrusion;
adding an organic solvent into the first opening to form a second opening on the light-emitting functional layer, wherein the second opening exposes at least a part of the conductive protrusion; and
forming a first electrode on the light-emitting function layer, wherein the first electrode is connected to the exposed part of the conductive protrusion.

Optionally, in some embodiments of the present application, the step of forming the conductive protrusion on the side of the auxiliary electrode away from the substrate comprises: providing a plurality of conductive droplets;
placing the plurality of the conductive droplets on the side of the auxiliary electrode away from the substrate;
solidifying the plurality of conductive droplets to form the conductive protrusion.

Optionally, in some embodiments of the present application, the material of the conductive droplet is a molten conductive metal or a conductive alloy.

Optionally, in some embodiments of the present application, in the step of adding the organic solvent into the first opening, a part of the light-emitting functional layer located in a center area of the conductive protrusion is dissolved by the organic solvent to form a mixture solution; and
after the step of adding the organic solvent into the first opening, the fabrication method further comprises:
removing the mixture solution to form the second opening.

### BENEFITS OF DISCLOSURE

### Benefits

Compared with the display panel in the prior art, the display panel provided by the present application is provided with a conductive protrusion on a side of the auxiliary electrode away from the substrate, and the first electrode extends from an inner wall of the first opening to the surface of the conductive protrusion, so that first electrode is effectively bridged with the auxiliary electrode through the conductive protrusion, thereby reducing an IR drop of the display panel and improving the display uniformity of the display panel.

### BRIEF DESCRIPTION OF DRAWINGS

### Brief Description of Drawings

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

FIG. 1 is a structural schematic diagram of a display panel provided by a first embodiment of the present application.

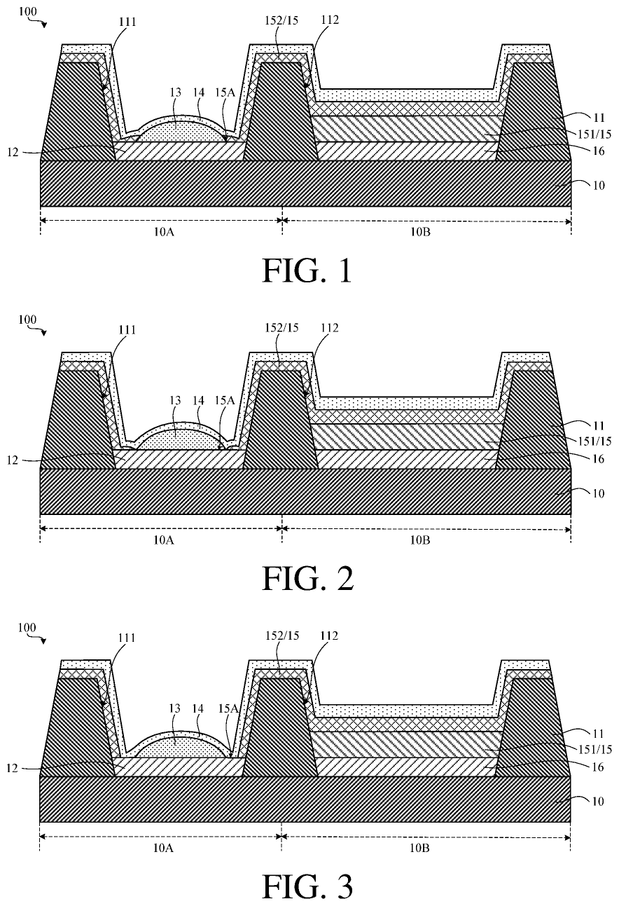

FIG. 2 is a structural schematic diagram of a display panel provided by a second embodiment of the present application.

FIG. 3 is a structural schematic diagram of a display panel provided by a third embodiment of the present application.

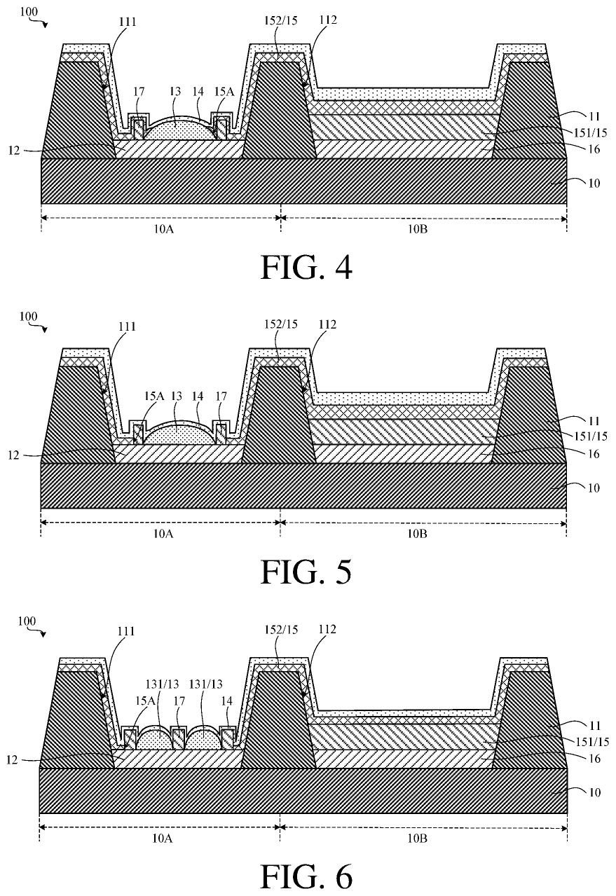

FIG. 4 is a structural schematic diagram of a display panel provided by a fourth embodiment of the present application.

FIG. 5 is a structural schematic diagram of a display panel provided by a fifth embodiment of the present application.

FIG. 6 is a structural schematic diagram of a display panel provided by a sixth embodiment of the present application.

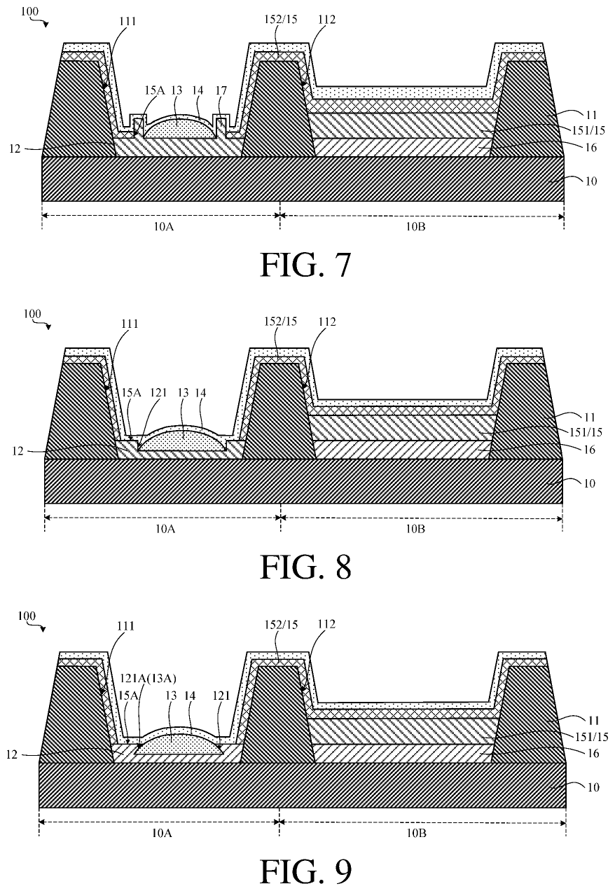

FIG. 7 is a structural schematic diagram of a display panel provided by a seventh embodiment of the present application.

FIG. 8 is a structural schematic diagram of a display panel provided by an eighth embodiment of the present application.

FIG. 9 is a structural schematic diagram of a display panel provided by a ninth embodiment of the present application.

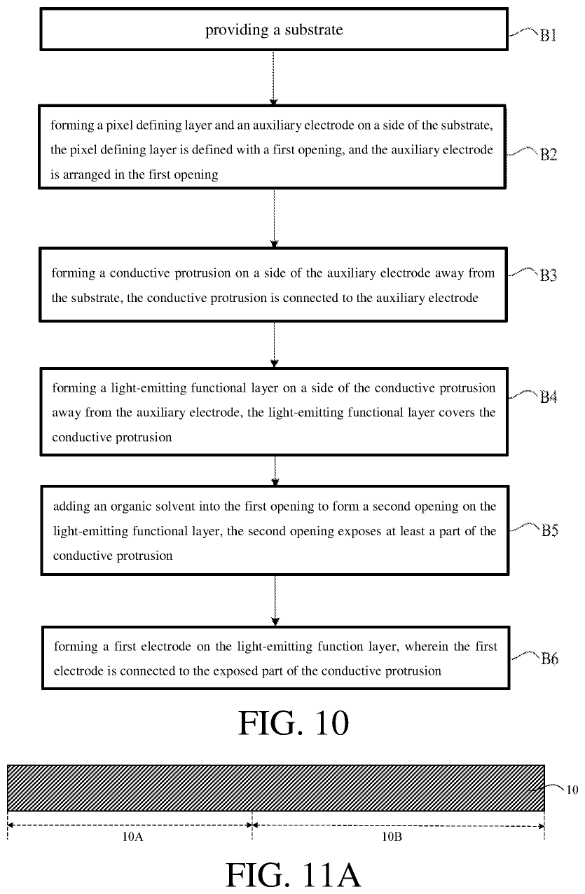

FIG. 10 is a schematic flowchart of a fabrication method of a display panel provided by an embodiment of the present application.

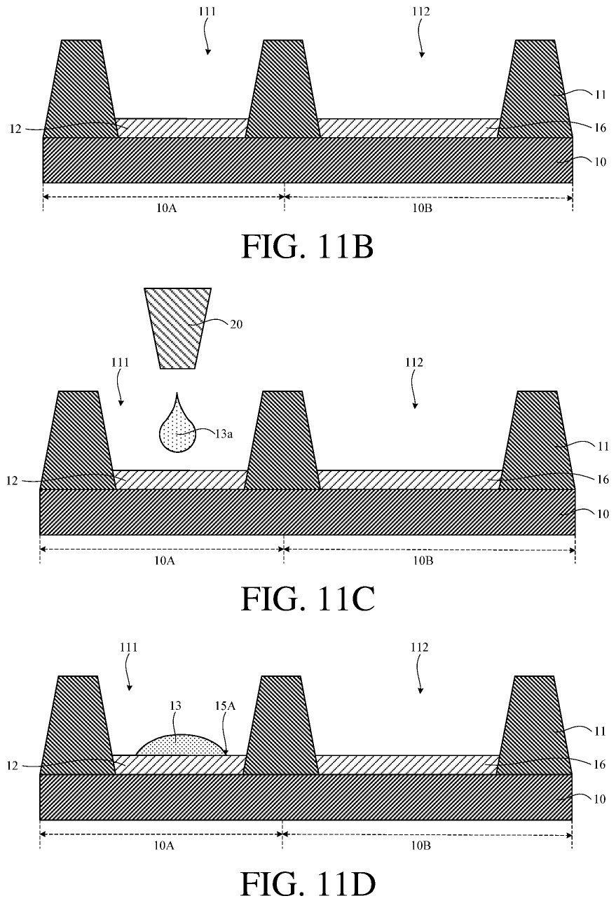

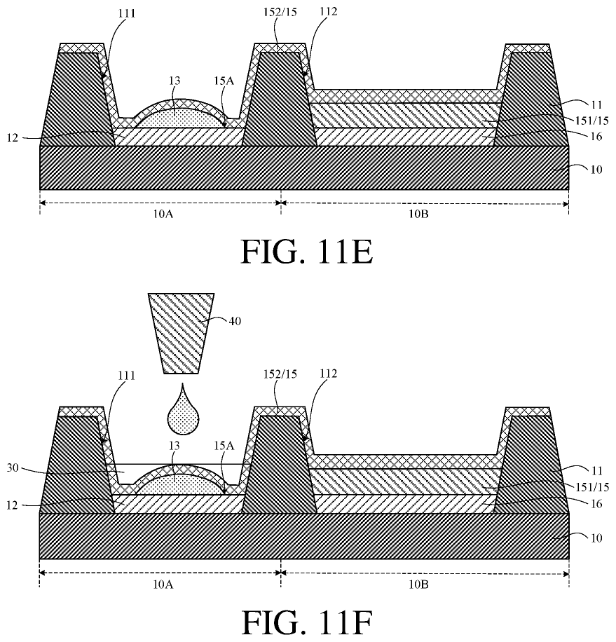

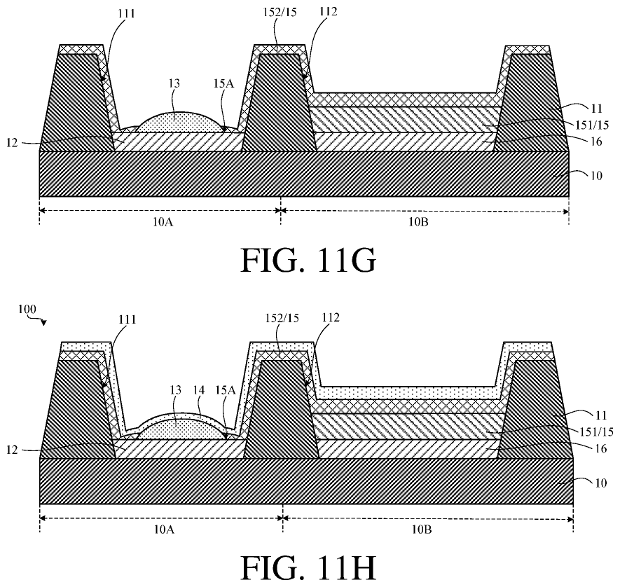

FIG. 11A to FIG. 11H are structural schematic diagrams sequentially obtained at each stage in the fabrication method of the display panel shown in FIG. 10.

### EMBODIMENTS OF DISCLOSURE

### Detailed Description

The technical solutions in the embodiments of the present application will be clearly and completely described below in coboundary with the drawings in the embodiments of the present application. Obviously, the described embodiments are only a portion of the embodiments of the present application, rather than all the embodiments. Based on the embodiments in the present application, all other embodiments obtained by those skilled in the art without creative work shall fall within the protection scope of the present application. In the present application, unless otherwise stated, directional words used such as “upper” and “lower” generally refer to the upper and lower directions of the device in actual use or working state, and specifically refer to the drawing directions in the drawings, and “inner” and “outer” refer to outlines of the device.

The embodiments of the present application provide a display panel and a fabrication method thereof, and an electronic device. Detailed descriptions are given below. It should be noted that the order of description in the following embodiments is not intended to limit the preferred order of the embodiments.

The present application provides a display panel, comprising a substrate, a pixel defining layer, an auxiliary electrode, a conductive protrusion, and a first electrode. The pixel defining layer is arranged on a side of the substrate, wherein a first opening is defined in the pixel defining layer. The auxiliary electrode is arranged on a side of the substrate, wherein the auxiliary electrode is arranged in the first opening. The conductive protrusion is arranged on a side of the auxiliary electrode away from the substrate, wherein the conductive protrusion is connected to the auxiliary electrode. The first electrode is arranged on a side of the conductive protrusion away from the auxiliary electrode, wherein the first electrode extends from an inner wall of the first opening to a surface of the conductive protrusion and is connected to the conductive protrusion.

Compared with the display panel in the prior art, the display panel provided by the present application is provided with a conductive protrusion on a side of the auxiliary electrode away from the substrate, and the first electrode extends from an inner wall of the first opening to the surface of the conductive protrusion, so that first electrode is effectively bridged with the auxiliary electrode through the conductive protrusion, thereby reducing an IR drop of the display panel and improving the display uniformity of the display panel.

The display panel provided by the present application will be described in detail below through specific embodiments.

Please refer to FIG. 1, a first embodiment of the present application provides a display panel 100, which comprises a substrate 10, a pixel defining layer 11, an auxiliary electrode 12, a conductive protrusion 13 and a first electrode 14. The pixel defining layer 11 is arranged on a side of the substrate 10. A first opening 111 is defined in the pixel defining layer 11. The auxiliary electrode 12 is arranged on a side of the substrate 10. The auxiliary electrode 12 is arranged in the first opening 111. The conductive protrusion 13 is arranged on a side of the auxiliary electrode 12 away from the substrate 10. The conductive protrusion 13 is connected to the auxiliary electrode 12. The first electrode 14 is arranged on a side of the conductive protrusion 13 away from the auxiliary electrode 12. The first electrode 14 extends from an inner wall of the first opening 111 to the surface of the conductive protrusion 13 and is connected to the conductive protrusion 13.

In the present embodiment, the display panel 100 further comprises a light-emitting functional layer 15. The light-emitting functional layer 15 is arranged between the auxiliary electrode 12 and the first electrode 14. The light-emitting functional layer 15 is defined with a second opening 15A. The second opening 15A exposes a part of the conductive protrusion 13. The first electrode 14 is connected to the exposed part of the conductive protrusion 13.

Specifically, the substrate 10 may be an array substrate. It should be noted that the array substrate comprises structures such as a base and thin film transistors arranged on the base (not shown in the figure). The related technologies are all existing technologies and will not be described here again.

The display panel 100 comprises an auxiliary electrode area 10A and a light-emitting pixel area 10B that are adjacently arranged. The first opening 111 is defined in the auxiliary electrode region 10A. A third opening 112 is further defined in the pixel defining layer 11. The third opening 112 is defined in the light-emitting pixel area 10B. In the present embodiment, the display panel 100 further comprises a second electrode 16. The second electrode 16 is arranged in the third opening 112. The second electrode 16 is provided between the substrate 10 and the light-emitting functional layer 15.

Herein, the first electrode 14 may be a cathode and the second electrode 16 may be an anode, or the first electrode 14 may also be an anode and the second electrode 16 may be a cathode. The present embodiment only takes the structure when the first electrode 14 is the cathode and the second electrode 16 is the anode as an example for description, but it is not limited thereto.

In the present embodiment, the auxiliary electrode 12 and the second electrode 16 are arranged in the same layer. Specifically, the auxiliary electrode 12 and the second electrode 16 are made by the same process. Among them, the auxiliary electrode 12 can be a two-layer structure of A/I or I/A, or a three-layer structure of I/A/I. Among them, the I can be IZO, ITO or Mo, the A can be metals such as Ag, Al, Ti or Cu, or alloys formed of at least two of the above-mentioned metals. In some embodiments, the auxiliary electrode 12 may be ITO/Ag, Al/ITO, or Ag/ITO/Ag.

It should be noted that in some embodiments, the auxiliary electrode 12 may also be provided in the same layer as the metal layer in the array substrate, such as the source electrode. In this case, the material of the auxiliary electrode 12 is the same as the material of the metal layer provided in the same layer. In the present embodiment, the position and material of the auxiliary electrode 12 are not specifically limited.

The light-emitting functional layer 15 comprises a first functional layer 151 and a second functional layer 152 sequentially arranged on the second electrode 16. Herein, the first functional layer 151 may be formed by an inkjet printing process and is a film layer only arranged in the third opening 112. For example, the first functional layer 151 may comprise a hole injection layer, a hole transport layer, and a light-emitting layer (not shown in the figure) arranged in sequence. Herein, the light-emitting layer may be an organic light-emitting layer or a quantum dot light-emitting layer. The second functional layer 152 may be formed by an evaporation process and cover a surface of the first functional layer 151 and the pixel defining layer 11 at the same time. For example, the second functional layer 152 may comprise an electron transport layer and an electron injection layer (not shown in the figure). In the present embodiment, the second opening 15A is defined in the second functional layer 152.

In the present embodiment, an orthographic projection of the conductive protrusion 13 on a plane where the substrate 10 is located is within an orthographic projection of the auxiliary electrode 12 on the plane where the substrate 10 is located. The second functional layer 152 extends from the inner wall of the first opening 111 and covers the edge of the conductive protrusion 13. The first electrode 14 extends along the second functional layer 152 to a surface of the conductive protrusion 13 and is connected to the conductive protrusion 13.

In the present embodiment, the conductive protrusion 13 is formed by the inkjet printing process. Here, a material of the conductive protrusion 13 can be a metal with a melting point lower than 300° C., such as Bi, Sn, Pb, or In, or an alloy composed of at least two of the foregoing metals. It should be noted that, in some embodiments, the material of the conductive protrusion 13 may also be other conductive materials, such as graphene, carbon nanotubes, etc. The present application does not specifically limit the material of the conductive protrusion 13.

Specifically, the surface of the conductive protrusion 13 away from the substrate 10 is a curved surface. Taking the material of the conductive protrusion 13 as a metal or alloy as an example, in the process of fabricating the conductive protrusion 13, a molten metal or alloy is dropped on the auxiliary electrode 12 through the inkjet printing process in advance, and after the metal or alloy in the melted-state is cooled, the conductive protrusion 13 with the curved surface is thus formed.

In the present embodiment, the material of the conductive protrusion 13 is an alloy. Compared with metal, on the one hand, the alloy has good electrical conductivity and can improve the conduction between the first electrode 14 and the auxiliary electrode 12. On the other hand, elongation performance of the alloy is better than that of metal, so it is easy to form a molten state, so that the conductive protrusion 13 can be formed based on the existing inkjet printing process, avoiding introduction of complicated equipment and increasing process cost.

Herein, a thickness of the first electrode 14 is 10 nm-200 nm. In some embodiments, the thickness of the first electrode 14 may be 10 nm, 50 nm, 80 nm, 100 nm, 120 nm, 150 nm, 180 nm, or 200 nm. Herein, the material of the first electrode 14 may be a combination of Ag, Mg/Ag alloy, Yb/Ag alloy, IZO single-layer or a multi-layer structure, and the like.

The display panel 100 provided in the present embodiment is provided with the conductive protrusions 13 on a side of the auxiliary electrode 12 away from the substrate 10, and the first electrode 14 extends from an inner wall of the first opening 111 to a surface of the conductive protrusion 13, so that the first electrode 14 achieves effective bridging with the auxiliary electrode 12 through the conductive protrusion 13, thereby reducing a IR drop of the display panel 100 and improving display uniformity of the display panel 100.

Please refer to FIG. 2, a second embodiment of the present application provides a display panel 100. The difference between the display panel 100 provided by the second embodiment of the present application and the first embodiment is that the second opening 15A completely exposes the conductive protrusion 13, and the second functional layer 152 is arranged adjacent to the conductive protrusion 13.

In the present embodiment, the second opening 15A completely exposes the conductive protrusions 13, thereby increasing an exposed area of the conductive protrusion 13 and increasing a contact area between the first electrode 14 and the conductive protrusion 13, thereby improving the conduction between the first electrode 14 and the auxiliary electrode 12, which is beneficial to reduce the IR drop of the display panel 100.

Referring to FIG. 3, a third embodiment of the present application provides a display panel 100. The difference between the display panel 100 provided by the third embodiment and the second embodiment of the present application is that the second opening 15A completely exposes the conductive protrusion 13, the light-emitting function layer 15 and the conductive protrusions 13 are spaced apart, a part of the auxiliary electrode 12 is also exposed by the second opening 15A, and the first electrode 14 is respectively connected to the conductive protrusion 13 and the exposed part of the auxiliary electrode 12.

In the present embodiment, while the first electrode 14 is indirectly bridging with the auxiliary electrode 12 through the conductive protrusion 13, a part of the auxiliary electrode 12 is exposed by the second opening 15A, so that the first electrode 14 can be exposed to the exposed auxiliary electrode 12 for directly bridging, thereby further improving the conduction between the first electrode 14 and the auxiliary electrode 12, greatly reducing the IR drop of the display panel 100, and further improving the display uniformity.

It should be noted that in the present embodiment, the exposed area of the auxiliary electrode 12 can be set according to a size of the opening of the second opening 15A. When the process conditions permit, the second opening 15A can completely expose the portion of the auxiliary electrode 12 not covered by the conductive protrusion 13 to maximize the conduction between the first electrode 14 and the auxiliary electrode 12.

Referring to FIG. 4, the fourth embodiment of the present application also provides a display panel 100. The difference between the display panel 100 provided in the fourth embodiment and the first embodiment of the present application is that the display panel 100 further includes a limiting portion 17, which is arranged on the auxiliary electrode 12 and located on a periphery of the conductive protrusion 13.

Since the conductive protrusion 13 in the present embodiment are formed by an inkjet printing process, the conductive protrusion 13 is in a droplet-shape before being formed on the auxiliary electrode 12. In the present embodiment, the limiting portion 17 is provided on the periphery of the conductive protrusion 13, so that during the formation of the conductive protrusion 13, the liquid droplet can be directly dropped on a receiving groove (not shown in the figure) formed by the limiting portion 17. Therefore, it is possible to reduce the probability that the droplets will level on the auxiliary electrode 12 after dropping, so as to improve a topography difference on a surface of the conductive protrusion 13. That is, this can increase a level difference between a center area and an edge area of the conductive protrusion 13 to increase a contact area between the first electrode 14 and the conductive protrusion 13, thereby improving the conduction between the first electrode 14 and the auxiliary electrode 12.

Referring to FIG. 5, the fifth embodiment of the present application also provides a display panel 100. The difference between the display panel 100 provided by the fifth embodiment and the fourth embodiment of the present application is that the limiting portion 17 is located in the second opening 15A, and the second opening 15A exposes at least a part of the limiting portion 17. The limiting portion 17 is a conductive structure, and the first electrode 14 is respectively connected to the conductive protrusion 13 and the exposed part of the limiting portion 17.

In the present embodiment, by setting the limiting portion 17 as a conductive structure, and exposing at least a part of the limiting portion 17 through the second opening 15A, the first electrode 14 can be connected to the auxiliary electrode 12 through the limiting portion 17, thereby further improving the conduction between the first electrode 14 and the auxiliary electrode 12, which is beneficial to further reduce the IR drop of the display panel 100.

Herein, the second opening 15A may expose a part of the limiting portion 17 or completely expose the limiting portion 17. When the second opening 15A completely exposes the limiting portion 17, the conduction between the first electrode 14 and the auxiliary electrode 12 can be maximized.

Please refer to FIG. 6, the sixth embodiment of the present application also provides a display panel 100. The difference between the display panel 100 provided by the sixth embodiment and the fifth embodiment of the present application is that the conductive protrusion 13 comprises at least two conductive protrusion portions 131, the at least two conductive protrusion portions 131 are arranged adjacent to each other, and a limiting portion 17 is provided on a periphery of each conductive protrusion portion 131, and the first electrode 14 is respectively connected to at the least two conductive protrusion portions 131.

Under the condition that the size of the second opening 15A remains unchanged, the above arrangement can further increase the surface area of the conductive protrusion 13 to increase the contact area between the conductive protrusion 13 and the first electrode 14, which is beneficial to improve the conduction of the first electrode 14 and the auxiliary electrode 12.

It should be noted that the present embodiment only illustrates the structure when the conductive protrusion 13 comprises two conductive protrusion portions 131. In some embodiments, the number of the conductive protrusion portions 131 may be three or more, and the number of the conductive protrusion portions 131 can be selected according to actual application requirements, and will not be repeated here.

Please refer to FIG. 7, the seventh embodiment of the present application further provides a display panel 100. The difference between the display panel 100 provided in the seventh embodiment and the fifth embodiment of the present application is that the limiting portion 17 and the auxiliary electrode 12 are integrally formed. Specifically, in the present embodiment, the limiting portion 17 and the auxiliary electrode 12 are simultaneously formed by the same mask.

Please refer to FIG. 8, the eighth embodiment of the present application further provides a display panel 100. The difference between the display panel 100 provided in the eighth embodiment and the first embodiment of the present application is that the auxiliary electrode 12 is provided with a groove 121 and the conductive protrusion 13 is arranged in the groove 121.

Since the conductive protrusion 13 in this embodiment is formed by an inkjet printing process, the conductive protrusion 13 is in the shape of droplets before being formed on the auxiliary electrode 12. In the present embodiment, the groove 121 is provided in the auxiliary electrode 12, so that during the formation of the conductive protrusion 13, the liquid droplet can be directly dropped into the groove 121, a probability of leveling of the droplets is reduced by limitation of an inner wall of the groove 121, and a topography difference on the surface of the conductive protrusion 13 is increased. That is, the above arrangement can increase the topography difference between the center area and the edge area of the conductive protrusion 13, thereby increasing the surface area of the conductive protrusion 13 to increase the contact area between the first electrode 14 and the conductive protrusion 13, thereby improving the conduction effect between the first electrode 14 and the auxiliary electrode 12.

Please refer to FIG. 9, the ninth embodiment of the present application also provides a display panel 100. The difference between the display panel 100 provided by the ninth embodiment and the eighth embodiment of the present application is that a surface of the groove 121 close to the conductive protrusion 13 is a first contact surface 121A, the surface of the conductive protrusion 13 close to the groove 121 is a second contact surface 13A, and the first contact surface 121A and the second contact surface 13A are connected and matched.

Herein, the first contact surface 121A is a sidewall of the groove 121. Since the surface of the conductive protrusion 13 is a curved surface, that is, the second contact surface 13A is a curved surface. Therefore, in the present embodiment, by setting the sidewalls of the groove 121 to be a curved surface that can match the conductive protrusion 13, and then when the conductive protrusion 13 is formed by the inkjet printing process, when the liquid droplets are dropped into the groove 121, the conductive protrusion 13 with a desired edge shape can be directly formed in the groove 121, thereby further reducing the probability of leveling of the droplets after dripping thereof.

It should be noted that the first contact surface 121A can be set according to the shape of the conductive protrusion 13. For example, when the second contact surface 13A is a flat surface, the first contact surface 121A can be set to a plane that match the second contact surface 13A and it won't repeat it here.

An embodiment of the present application also provides an electronic device, and the electronic device may be a mobile phone, a tablet, a notebook computer, or a television. The electronic device comprises a housing and a display panel arranged in the housing. The display panel may be the display panel 100 described in any of the foregoing embodiments. The specific structure of the display panel 100 may refer to that of the foregoing embodiment. The description will not be repeated here.

Referring to FIG. 10, an embodiment of the present application provides a fabrication method of a display panel, which comprises following steps:
B1: providing a substrate;
B2: forming a pixel defining layer and an auxiliary electrode on a side of the substrate, wherein the pixel defining layer is defined with a first opening, and the auxiliary electrode is arranged in the first opening;
B3: forming a conductive protrusion on a side of the auxiliary electrode away from the substrate, wherein the conductive protrusion is connected to the auxiliary electrode;
B4: forming a light-emitting functional layer on a side of the conductive protrusion away from the auxiliary electrode, wherein the light-emitting functional layer covers the conductive protrusion;
B5: adding an organic solvent into the first opening to form a second opening on the light-emitting functional layer, wherein the second opening exposes at least a part of the conductive protrusion; and
B6: forming a first electrode on the light-emitting function layer, wherein the first electrode is connected to the exposed part of the conductive protrusion.

Therefore, the fabrication method of the display panel provided by the present embodiment forms a conductive protrusion on a side of the auxiliary electrode away from the substrate in advance. After the light-emitting functional layer is formed and a surface of the conductive protrusion has differences in topography, so that the light-emitting functional layer covering the conductive protrusion also has differences in topography. Furthermore, after adding organic solvent to the first opening, a part of the light-emitting function layer located in the higher topography area will dissolve in the organic solvent, and then flow to the low topography area and being precipitated, thus making the part of the conductive protrusion located in the high topography area is exposed. That is, a second opening that exposes the conductive protrusion is formed on the light-emitting function layer, and then after the first electrode is formed, the first electrode can be directly connected to the exposed part of the conductive protrusion to realize the conduction between the first electrode and the auxiliary electrode, thereby reducing the IR drop of the display panel and improving the display uniformity of the display panel.

Please refer to FIG. 10 and FIGS. 11A-11G together, and the fabrication method of the display panel 100 provided in this embodiment will be described in detail below.

Step B1: providing a substrate 10, as shown in FIG. 11A.

Herein, the substrate 10 has an auxiliary electrode area 10A and a light-emitting pixel area 10B arranged adjacently. The substrate 10 may be an array substrate. It should be noted that the array substrate comprises a base and a thin film transistor formed on the base and other structures (not shown in the figure). The related technologies are all existing technologies and will not be repeated here.

Step B2: forming a pixel defining layer 11 and an auxiliary electrode 12 on a side of the substrate 10. The pixel defining layer 11 is defined with a first opening 111, and the auxiliary electrode 12 is arranged in the first opening 111, as shown in FIG. 11B.

Herein, the first opening 111 is defined in the auxiliary electrode area 10A. The pixel defining layer 11 is further provided with a third opening 112, the third opening 112 is defined in the light-emitting pixel region 10B, and the second electrode 16 is formed in the third opening 112. Among them, the second electrode 16 is an anode. The auxiliary electrode 12 and the second electrode 16 may be formed at the same time as.

Specifically, the auxiliary electrode 12 can be a two-layer structure of A/I or I/A, or a three-layer structure of I/A/I. Among them, I can be selected as IZO, ITO or Mo, and A can be selected as Ag, Al, Ti or Cu, or an alloy formed from at least two of the above metals. In some embodiments, the auxiliary electrode 12 may be ITO/Ag, Al/ITO, or Ag/ITO/Ag.

Step B3: forming a conductive protrusion 13 is formed on a side of the auxiliary electrode 12 away from the substrate 10, and the conductive protrusion 13 is connected to the auxiliary electrode 12.

Among them, the step B3 specifically comprises following steps:

Step B31: providing a plurality of conductive droplets 13a;

Among them, the material of the conductive droplet 13a is a molten conductive metal or a conductive alloy. Herein, a melting point of the conductive metal is lower than 300° C. The conductive metal may be Bi, Sn, Pb or In. The conductive alloy may be an alloy formed of at least two conductive metals mentioned above. It should be noted that, in some embodiments, the material of the conductive droplet 13a can also be other conductive materials that is conductive and can be form as droplets, which will not be repeated here.

In the present embodiment, the material of the conductive droplet 13a is an alloy, and the molten conductive droplet 13a is formed by heating the alloy. Compared with metals, the alloy has good electrical conductivity on one hand, and the alloys has better elongation properties than metals on the other hand, so they are easy to form a molten state.

Step B32: placing the plurality of the conductive droplets 12 on a side of the auxiliary electrode 12 away from the substrate 10, as shown in FIG. 11C;

Since the material of the conductive droplets 13a in the present embodiment is an alloy, and the alloy is easy to form a molten state. Therefore, the present embodiment can drop the conductive droplets 13a into the first opening 111 based on the existing inkjet printing process, avoiding introduction of complicated instruments and equipment which increases the process cost. Specifically, the first inkjet printing component 20 may be used to drop the conductive liquid droplet 13a on the auxiliary electrode 12 in the first opening 111, and a diameter of the conductive liquid droplet 13a may be 5 μm-20 μm. Herein, the first inkjet printing component 20 may comprise elements such as a nozzle head and a nozzle (not shown in the figure).

Step B33: solidifying the plurality of conductive droplets 13a to form the conductive protrusion, as shown in FIG. 11D.

After the conductive liquid droplets 13a are dropped on the auxiliary electrode 12, it is cooled until the conductive liquid droplets 13a are solidified, that is, the conductive protrusion 13 is formed.

Step B4: forming a light-emitting functional layer 15 on a side of the conductive protrusion 13 away from the auxiliary electrode 12, and the light-emitting functional layer 15 covers the conductive protrusion 13, as shown in FIG. 11E.

Specifically, the light-emitting functional layer 15 comprises a first functional layer 151 and a second functional layer 152 sequentially formed on the second electrode 16. The second functional layer 152 extends from an inner wall of the first opening 111 and covers an edge of the conductive protrusion 13.

Herein, the first functional layer 151 may be formed by an inkjet printing process and is only a film layer arranged in the third opening 112. For example, the first functional layer 151 may comprise a hole injection layer and a hole transport layer and a light-emitting layer arranged in sequence (not shown in the figure), wherein the light-emitting layer may be an organic light-emitting layer or a quantum dot light-emitting layer. The second functional layer 152 may be formed by an evaporation process and cover the surface of the first functional layer 151 and the pixel defining layer 11 at the same time. For example, the second functional layer 152 may comprise an electron transport layer and an electron injection layer (not shown in the figure).

Step B5: adding an organic solvent 30 into the first opening 111 to form a second opening 15A on the light-emitting function layer 15. The second opening 15A exposes at least a part of the conductive protrusion 13, as shown in FIGS. 11F and 11G.

Due to the difference in topography on the surface of the conductive protrusion 13, for example, the topography of the center area of the conductive protrusion 13 is higher than that of the edge area. Therefore, when the organic solvent 30 is added to the first opening 111, the organic solvent 30 at least completely covers the conductive protrusion 13, as shown in FIG. 11F, to dissolve the light-emitting functional layer 15 located in the center area of the conductive protrusion 13 to form a mixture solution of the light-emitting functional material and the organic solvent 30. Herein, the light-emitting functional material is a material of the portion of the light-emitting functional layer 15 located in the first opening 111.

Herein, the organic solvent 30 may be an organic solvent 30 of a high boiling point such as trimethylbenzene, dichlorobenzene, or diphenyl ether. It should be noted that the type of the organic solvent 30 can be selected according to the type of the light-emitting functional material as long as it can dissolve the light-emitting functional material, and it is within the protection scope of the present application. Specifically, the second inkjet printing component 40 is used to add the organic solvent 30 into the first opening 111. Herein, the second inkjet printing component 40 may comprise elements such as a nozzle head and a nozzle (not shown in the figure).

After the step B5, the method further comprises a step of removing the mixture solution to form a second opening 15A in the light-emitting functional layer 15 that at least exposes the center area of the conductive protrusion 13, as shown in FIG. 11G.

Herein, vacuum suction and thermal baking can be used to remove the light-emitting functional material and the organic solvent 30 in the mixture solution.

Step B6: forming a first electrode 14 on the light-emitting function layer 15, and the first electrode 14 is connected to the exposed part of the conductive protrusion 13, as shown in FIG. 11H.

Herein, the first electrode 14 extends along the second functional layer 152 to the surface of the conductive protrusion 13 and is connected to the conductive protrusion 13. The first electrode 14 is a cathode. A thickness of the first electrode 14 is 10 nm-200 nm. In some embodiments, the thickness of the first electrode 14 may be 10 nm, 50 nm, 80 nm, 100 nm, 120 nm, 150 nm, 180 nm, or 200 nm. A material of the first electrode 14 may be a combination of a single-layer or a multilayer structure of Ag, Mg/Ag alloy, Yb/Ag alloy, IZO, and the like. Specifically, the first electrode 14 may be formed by an evaporation process or a magnetron sputtering process.

Thus, the fabrication method of the display panel 100 of the present embodiment is completed.

It should be noted that the display panel 100 provided in the first embodiment of the present application can be obtained by the above-mentioned fabrication method of the display panel. For the display panel 100 provided in the second and third embodiments, the fabrication method is the same as that of the first embodiment and will not be repeated here.

For the display panel 100 provided in the fourth embodiment of the present application, the fabrication method is different from the fabrication method of the display panel 100 provided in the first embodiment in that: before forming the conductive protrusion 13, the limiting portion 17 is formed on the surface of the auxiliary electrodes 12 away from the substrate 10, and a receiving groove (not marked in the figure) is defined on a side of the limiting portion 17 away from the auxiliary electrode 12. By forming the limiting portion 17 on the auxiliary electrode 12 in advance, when the conductive protrusion 13 is formed, the conductive droplets can be directly dropped into the receiving groove formed by the limiting portion 17, thereby reducing the leveling probability of the conductive droplets after drop off thereof.

It should be noted that the fabrication method of the display panel 100 provided in the fifth embodiment and the sixth embodiment of the present application is the same as the fabrication method of the display panel 100 provided in the fourth embodiment, and will not be repeated here.

For the display panel 100 provided in the seventh embodiment of the present application, the fabrication method is different from the fabrication method of the display panel 100 provided in the fourth embodiment in that: before forming the conductive protrusion 13, a photomask is first used to form the auxiliary electrode 12 and the limiting portion 17, and make the limiting portion 17 and the auxiliary electrode 12 an integral structure; and then another mask is used to separately form the second electrode 16.

For the display panel 100 provided in the eighth embodiment of the present application, the fabrication method is different from the fabrication method of the display panel 100 provided in the seventh embodiment in that: after the auxiliary electrode 12 and the second electrode 16 are formed, a photomask is used to form the groove 121 in the auxiliary electrode 12, and then the conductive protrusion 13 is fabricated.

It should be noted that the fabrication method of the display panel 100 provided in the ninth embodiment of the present application is the same as the fabrication method of the display panel 100 provided in the eighth embodiment, and will not be repeated here.

The above is a detailed introduction to a display panel and a fabrication method thereof, and an electronic device provided by the embodiments of the present invention, and specific examples are used in this article to illustrate the principles and implementations of the present invention. Specific examples are used in this article to illustrate the principles and implementation of the present application. Its core idea, at the same time, for those skilled in the art, according to the idea of the present application, there will be changes in the specific implementation and scope of application. In summary, the content of the present specification should not be construed as a limitation to the present application.

What is claimed is:

1. A display panel comprising:
a substrate;
a pixel defining layer arranged on a side of the substrate, wherein a first opening is defined in the pixel defining layer;
an auxiliary electrode arranged on a side of the substrate, wherein the auxiliary electrode is arranged in the first opening;
a conductive protrusion arranged on a side of the auxiliary electrode away from the substrate, wherein the conductive protrusion is connected to the auxiliary electrode; and
a first electrode arranged on a side of the conductive protrusion away from the auxiliary electrode, wherein the first electrode extends from an inner wall of the first opening to a surface of the conductive protrusion and is connected to the conductive protrusion.

2. The display panel according to claim 1, wherein the display panel further comprises a light-emitting functional layer, wherein the light-emitting functional layer is located between the auxiliary electrode and the first electrode, and a second opening is defined in the light-emitting functional layer, and the second opening exposes at least a part of the conductive protrusion, and the first electrode is connected to the exposed part of the conductive protrusion.

3. The display panel of claim 2, wherein the light-emitting functional layer covers an edge of the conductive protrusion.

4. The display panel of claim 2, wherein the light-emitting functional layer and the conductive protrusions are spaced apart, the second opening also exposes a part of the auxiliary electrode, and the first electrode is respectively connected to the conductive protrusion and the exposed part of the auxiliary electrode.

5. The display panel of claim 1, wherein the display panel further comprises a limiting portion, and the limiting portion is arranged on the auxiliary electrode and located on a periphery of the conductive protrusion.

6. The display panel according to claim 5, wherein the conductive protrusion comprises at least two conductive protrusion portions, the at least two conductive protrusion portions are arranged adjacent to each other, the limiting portion is arranged on the periphery of each of the conductive protrusion portion, and the first electrode is respectively connected with the at least two conductive protrusion portions.

7. The display panel of claim 5, wherein the limiting portion is arranged in the second opening, the second opening exposes at least a part of the limiting portion, the limiting portion is a conductive structure, and the first electrode is respectively connected with the conductive protrusion and the exposed part of the limiting portion.

8. The display panel of claim 7, wherein the limiting portion and the auxiliary electrode are integrally formed.

9. The display panel of claim 1, wherein a groove is defined in the auxiliary electrode, and the conductive protrusion is arranged in the groove.

10. The display panel of claim 9, wherein a surface of the groove close to the conductive protrusion is a first contact surface, a surface of the conductive protrusion close to the groove is a second contact surface, and the first contact surface and the second contact surface are connected and matched.

11. The display panel of claim 1, wherein an orthographic projection of the conductive protrusion on a plane where the substrate is located is within an orthographic projection of the auxiliary electrode on the plane where the substrate is located.

12. The display panel of claim 11, wherein the display panel comprises an auxiliary electrode area and a light-emitting pixel area that are adjacently arranged, the first opening is defined in the auxiliary electrode area, a third opening is defined in the pixel defining layer, and the third opening is defined in the light-emitting pixel area; and
the display panel further comprises a second electrode arranged on the substrate and defined in the third opening, the second electrode and the auxiliary electrode are arranged in the same layer, and the second electrode is arranged in the light-emitting pixel area.

13. An electronic device, wherein the electronic device comprises a housing and a display panel arranged in the housing, and the display panel comprises:
a substrate;
a pixel defining layer arranged on a side of the substrate, wherein a first opening is defined in the pixel defining layer;
an auxiliary electrode arranged on a side of the substrate, wherein the auxiliary electrode is arranged in the first opening;
a conductive protrusion arranged on a side of the auxiliary electrode away from the substrate, wherein the conductive protrusion is connected to the auxiliary electrode; and
a first electrode arranged on a side of the conductive protrusion away from the auxiliary electrode, wherein the first electrode extends from an inner wall of the first opening to a surface of the conductive protrusion and is connected to the conductive protrusion.

14. The electronic device according to claim 13, wherein the display panel further comprises a light-emitting functional layer, wherein the light-emitting functional layer is located between the auxiliary electrode and the first electrode, and a second opening is defined in the light-emitting functional layer, and the second opening exposes at least a part of the conductive protrusion, and the first electrode is connected to the exposed part of the conductive protrusion.

15. The electronic device according to claim 14, wherein the light-emitting functional layer and the conductive protrusion are spaced apart, the second opening also exposes a part of the auxiliary electrode, and the first electrode is respectively connected to the conductive protrusion and the exposed part of the auxiliary electrode.

16. The electronic device according to claim 13, wherein the display panel further comprises a limiting portion, and the limiting portion is arranged on the auxiliary electrode and located on a periphery of the conductive protrusion.

17. A fabrication method of a display panel, comprising following steps:
providing a substrate;
forming a pixel defining layer and an auxiliary electrode on a side of the substrate, wherein the pixel defining layer is defined with a first opening, and the auxiliary electrode is arranged in the first opening;
forming a conductive protrusion on a side of the auxiliary electrode away from the substrate, wherein the conductive protrusion is connected to the auxiliary electrode;
forming a light-emitting functional layer on a side of the conductive protrusion away from the auxiliary electrode, wherein the light-emitting functional layer covers the conductive protrusion;
adding an organic solvent into the first opening to form a second opening on the light-emitting functional layer, wherein the second opening exposes at least a part of the conductive protrusion; and
forming a first electrode on the light-emitting function layer, wherein the first electrode is connected to the exposed part of the conductive protrusion.

18. The fabrication method of the display panel according to claim 17, wherein the step of forming the conductive protrusion on the side of the auxiliary electrode away from the substrate comprises:
providing a plurality of conductive droplets;
placing the plurality of the conductive droplets on the side of the auxiliary electrode away from the substrate;
solidifying the plurality of conductive droplets to form the conductive protrusion.

19. The fabrication method of the display panel according to claim 17, wherein the material of the conductive droplet is a molten conductive metal or a conductive alloy.

20. The fabrication method of the display panel according to claim 17, wherein in the step of adding the organic solvent into the first opening, a part of the light-emitting functional layer located in a center area of the conductive protrusion is dissolved by the organic solvent to form a mixture solution; and
after the step of adding the organic solvent into the first opening, the fabrication method further comprises:
removing the mixture solution to form the second opening.
